(19) United States
(12) Patent Application Publication
(10) Pub. No.: US 2012/0025054 A1
(43) Pub. Date: Feb. 2, 2012

(54) HOLDING APPARATUS, CONVEYING APPARATUS, AND ROTATION-TRANSMITTING APPARATUS

(76) Inventors: Kazuhiro Musha, Kanagawa (JP); Hirofumi Minami, Kanagawa (JP); Hidenobu Anzai, Saitama (JP); Koji Sakurai, Saitama (JP); Tojiro Aoyama, Kanagawa (JP); Yasuhiro Kakinuma, Kanagawa (JP)

(21) Appl. No.: 13/262,195

(22) PCT Filed: Mar. 30, 2010
(86) PCT No.: PCT/JP2010/002332

§ 371 Date: Sep. 29, 2011

(30) Foreign Application Priority Data
Mar. 31, 2009 (JP) 2009-087480

(51) Int. Cl. H01L 21/677; F16D 3/48; B65G 49/07; F16M 11/12; B25J 15/00

(52) U.S. Cl. 248/371; 294/81.51; 464/137

(57) ABSTRACT

A holding apparatus, a conveying apparatus, and a rotation-transmitting apparatus are provided that are capable of holding an object in a tiltable manner. A conveying apparatus according to one form of the present invention includes a pad supported by a supporting member on a hand. A concave portion is formed on the pad, and by the concave portion engaging with the supporting member fixed to the hand, a pad is supported in a tiltable manner. A conveying object is held by an adhesive layer of the pad adhering thereto. By tilting with respect to the hand , the pad follows the shape or vibration of the conveying object, with the result that the conveying object can be conveyed stably.

### TECHNICAL FIELD

The present invention relates to a holding apparatus that holds an object in an inclinable manner, a conveying apparatus, and a rotation-transmitting apparatus.

### BACKGROUND ART

As one type of conveying apparatus that conveys semiconductor substrates for LSI (Large Scale Integration), glass substrates for display, and the like (hereinafter, referred to as substrate), there is a conveying apparatus that holds a substrate using a hand attached at a tip end of a robot arm. Such a conveying apparatus requires a substrate to be surely held and also requires high positioning accuracy, and there are various types of holding mechanisms for holding a substrate on a hand.

Patent Document 1 discloses a substrate conveying hand in which a metal film having a small radiation factor on a surface on which a substrate is mounted is formed. The substrate conveying hand suppresses, as well as suppress a temperature rise at a time a hand enters a heating chamber, a deposition chamber, and the like, a heat transfer to the substrate mounted on the hand. As a result, it becomes possible to prevent warpage of the substrate from occurring due to a thermal deformation and stably and favorably convey the substrate.

Patent Document 1: Japanese Patent Application Laid-open No. 2006-237256 (paragraph [0024], FIG. 2)

### DISCLOSURE OF THE INVENTION

### Problems to be Solved by the Invention

However, while the substrate conveying hand disclosed in Patent Document 1 is capable of stably conveying an undeformed substrate by preventing a thermal deformation of the substrate, a stable conveyance of a deformed substrate is not mentioned. Although the substrate is held by being mounted on a substrate mounting portion of the planar hand, when the substrate is deformed, a substrate holding property is prominently impaired due to a reduction of a contact area between the substrate and the substrate mounting portion.

In view of the circumstances as described above, it is an object of the present invention to provide a holding apparatus, a conveying apparatus, and a rotation-transmitting apparatus that are capable of stably holding an object while suppressing an influence of a change in shape of the object.

### Means for Solving the Problems

According to an embodiment of the present invention, there is provided a holding apparatus including a base portion, a holding portion, and a supporting portion.

The holding portion includes a first surface that holds a holding object and a second surface opposing the base portion.

The supporting portion is provided between the base portion and the second surface and supports the holding portion in a state where the holding portion is tiltable with respect to the base portion.

According to an embodiment of the present invention, there is provided a conveying apparatus that conveys a conveying object and includes a hand, a holding portion, and a supporting portion.

The hand includes a mounting surface on which the conveying object is mounted.

The holding portion includes a first surface that holds the conveying object and a second surface opposing the mounting surface.

The supporting portion is provided between the mounting surface and the second surface and supports the holding portion in a state where the holding portion is tiltable with respect to the mounting surface.

According to an embodiment of the present invention, there is provided a rotation-transmitting apparatus including a first spinning disk, a transmitting portion, a concave portion, a supporting portion, an engaging portion, and a second spinning disk.

The transmitting portion includes a first surface and a second surface opposing the first spinning disk.

The concave portion is formed on either one of the first spinning disk and the second surface.

The supporting portion is constituted of an inelastic body, is provided between the first spinning disk and the second surface, and supports the transmitting portion in a state where the transmitting portion is tiltable with respect to the first spinning disk by engaging with the concave portion.

The engaging portion is provided on a circumference of the supporting portion and engages the first spinning disk and the transmitting portion in a rotating direction.

The second spinning disk comes into contact with the first surface.

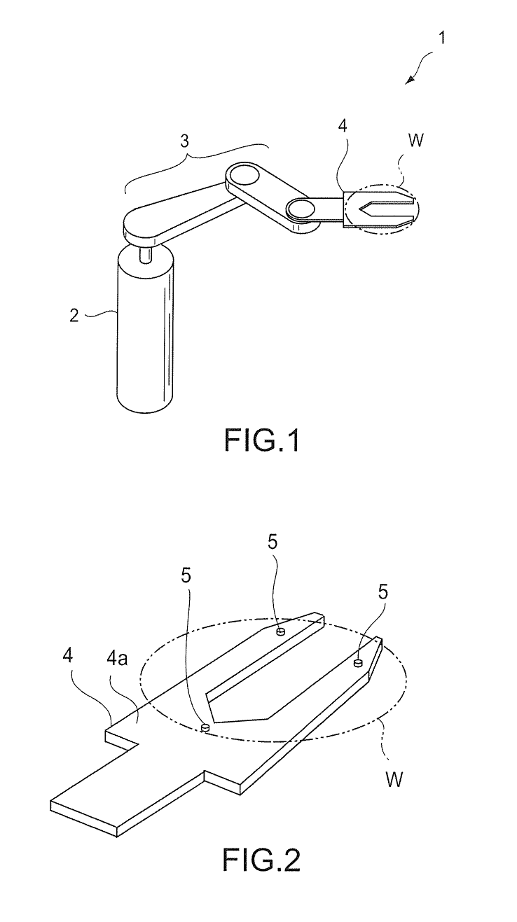

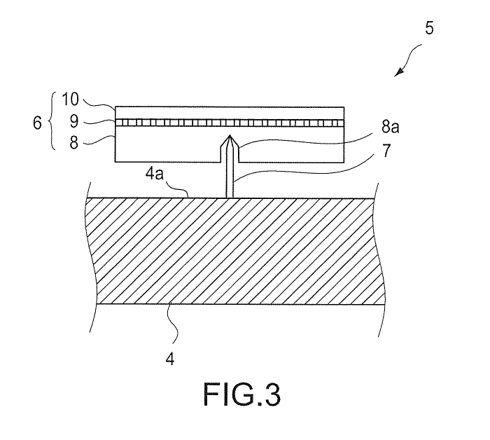

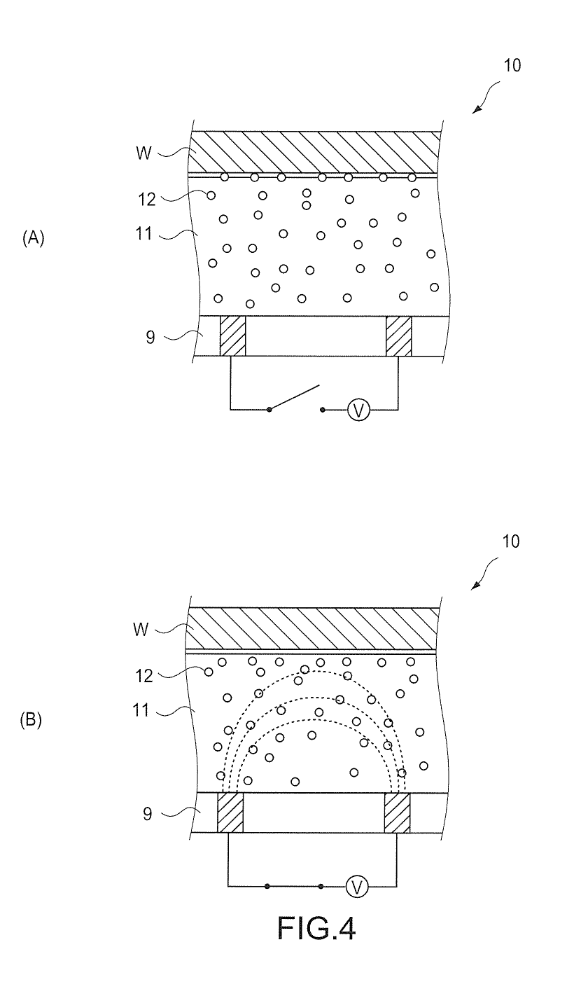

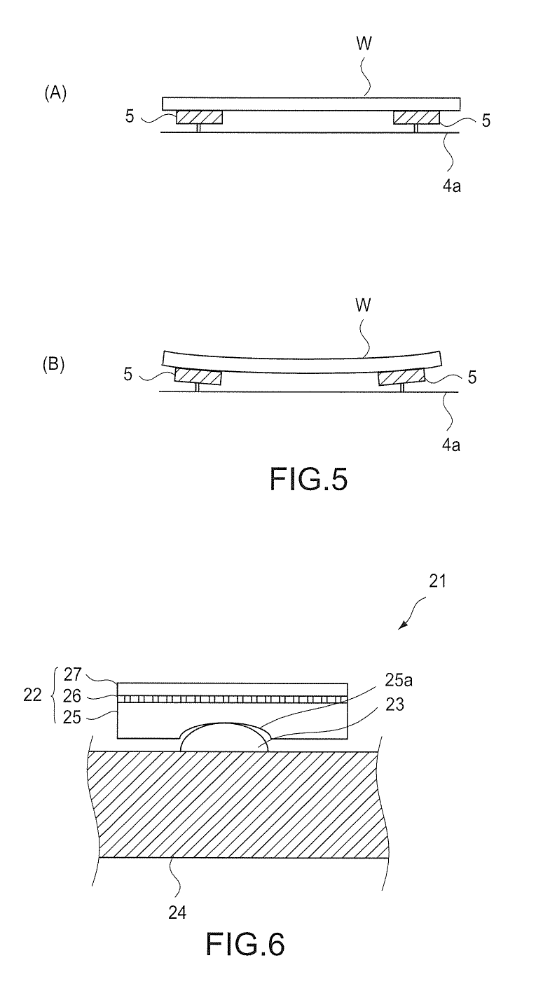

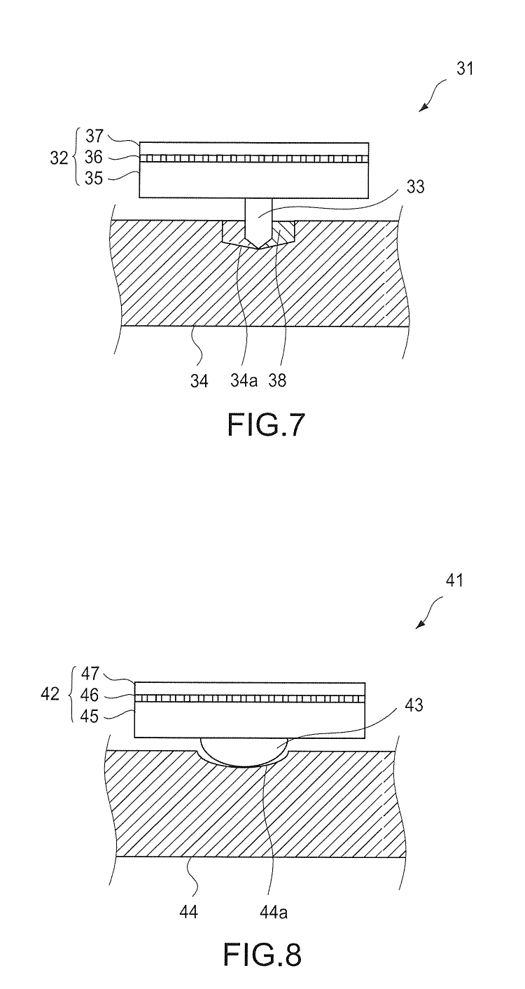

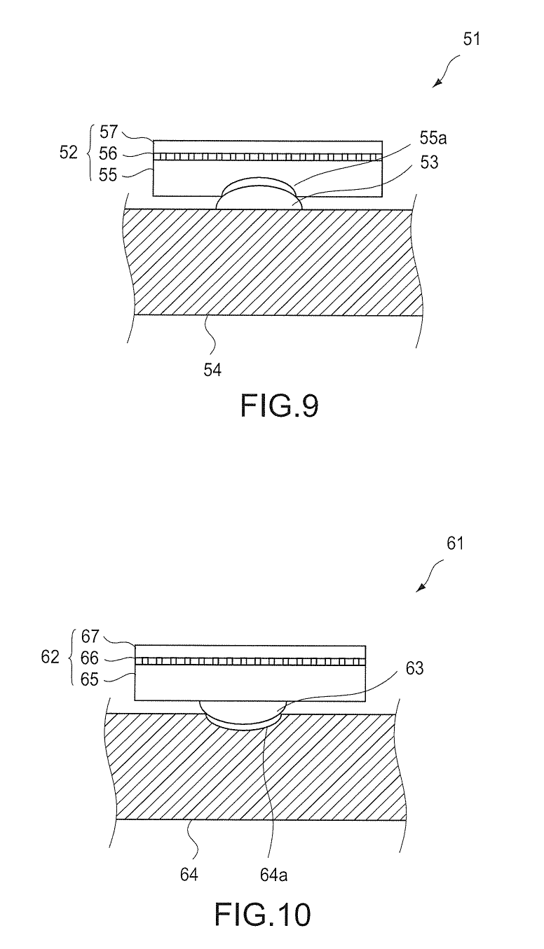

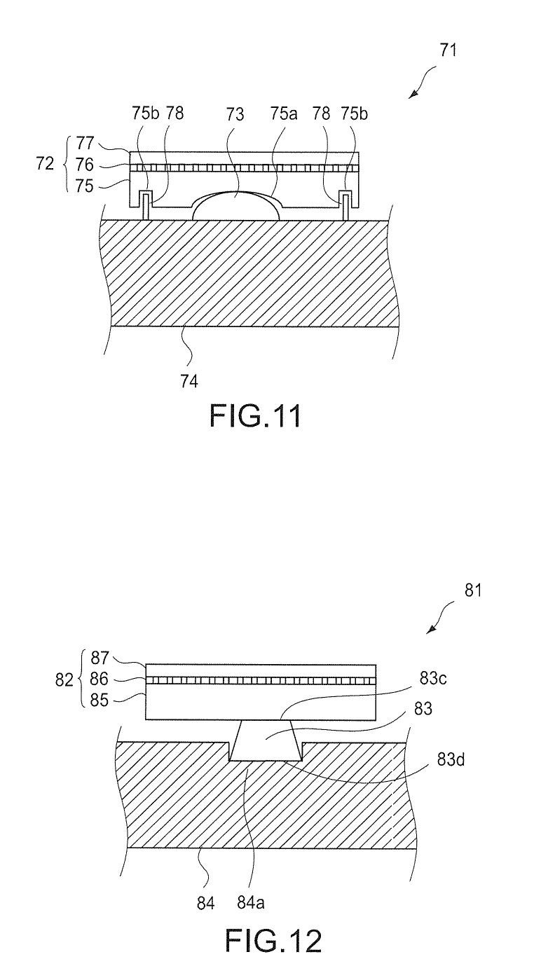

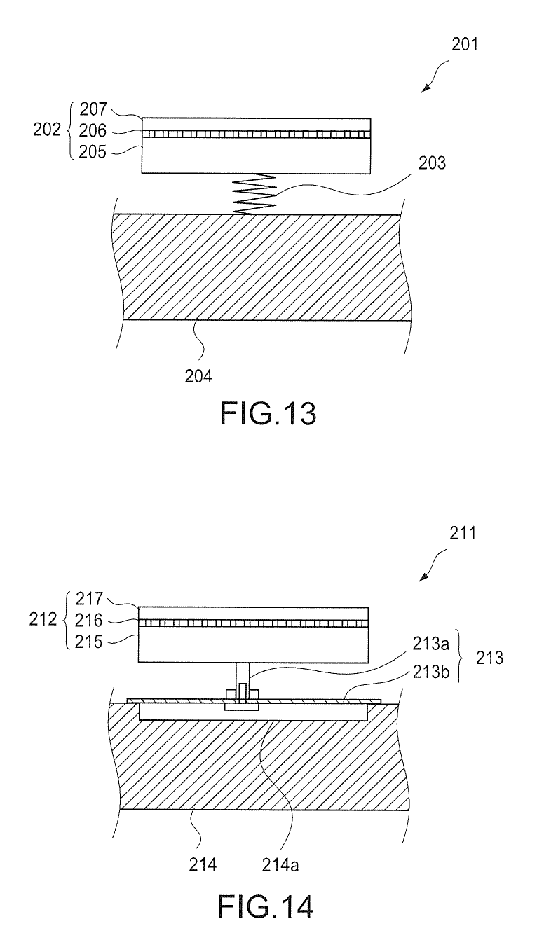

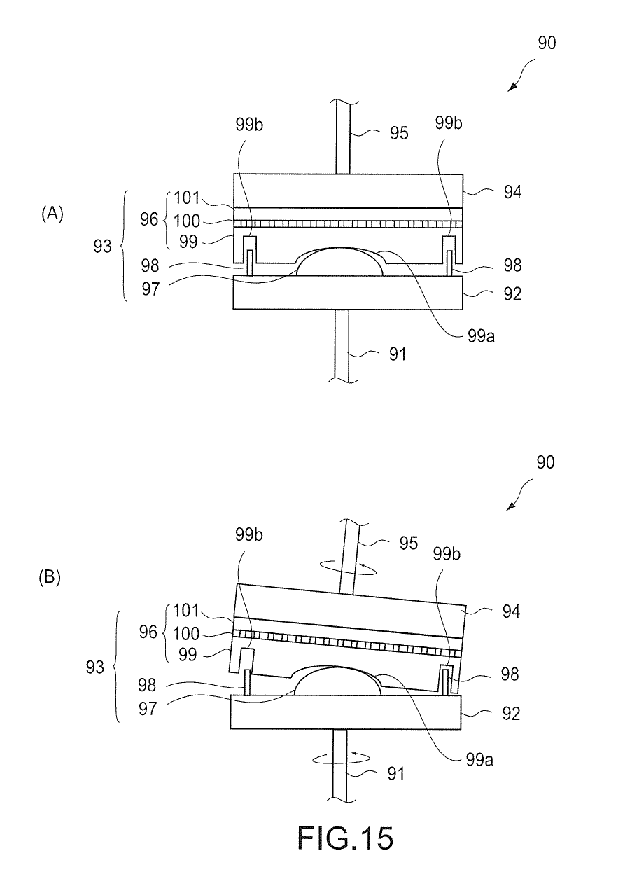

### BRIEF DESCRIPTION OF DRAWINGS

[FIG. 1] A perspective view showing a conveying apparatus according to a first embodiment.

[FIG. 2] A perspective view showing a hand of the conveying apparatus according to the first embodiment.

[FIG. 3] A cross-sectional diagram showing a holding mechanism of the conveying apparatus according to the first embodiment.

[FIG. 4] Schematic diagrams showing an adhesive layer of the conveying apparatus according to the first embodiment.

[FIG. 5] Schematic diagrams showing states where the holding mechanisms of the conveying apparatus according to the first embodiment are holding a substrate.

[FIG. 6] A cross-sectional diagram showing a holding mechanism according to a second embodiment.

[FIG. 7] A cross-sectional diagram showing a holding mechanism according to a third embodiment.

[FIG. 8] A cross-sectional diagram showing a holding mechanism according to a fourth embodiment.

[FIG. 9] A cross-sectional diagram showing a holding mechanism according to a fifth embodiment.

[FIG. 10] A cross-sectional diagram showing a holding mechanism according to a sixth embodiment.

[FIG. 11] A cross-sectional diagram showing a holding mechanism according to a seventh embodiment.

[FIG. 12] A cross-sectional diagram showing a holding mechanism according to an eighth embodiment.

[FIG. 13] A cross-sectional diagram showing a holding mechanism according to a ninth embodiment.

[FIG. 14] A cross-sectional diagram showing a holding mechanism according to a tenth embodiment.

[FIG. 15] Cross-sectional diagrams each showing a rotation-transmitting apparatus according to an eleventh embodiment.

### BEST MODES FOR CARRYING OUT THE INVENTION

According to an embodiment of the present invention, there is provided a holding apparatus including a base portion, a holding portion, and a supporting portion.

The holding portion includes a first surface that holds a holding object and a second surface opposing the base portion.

The supporting portion is provided between the base portion and the second surface and supports the holding portion in a state where the holding portion is tiltable with respect to the base portion.

The holding apparatus holds the holding object using the first surface of the holding portion. Since the holding portion is supported by the supporting portion such that it is tiltable with respect to the substrate, the holding portion easily follows the deformation of the substrate. Therefore, according to the holding apparatus, it is possible to stably hold the substrate irrespective of the shape of the holding object.

In the holding apparatus, either one of the base portion and the second surface may include a concave portion formed thereon, and the supporting portion may be constituted of an inelastic body and engage with the concave portion.

With this structure, by engaging with the concave portion, the supporting portion can hold the holding portion in a state where it is tiltable with respect to the substrate. Further, since the supporting portion is constituted of an inelastic body, it is possible to stably hold the substrate without the holding portion vibrating with respect to the base portion due to an inertial force generated by the movement of the base portion.

The supporting body may be constituted of an elastic body.

With this structure, by an elastic deformation, the supporting portion can hold the holding portion such that it is tiltable with respect to the substrate.

The concave portion may be formed on the second surface, and the supporting portion may be a convex portion that is fixed to the base portion, protrudes toward the holding portion, and comes into contact with a bottom portion of the concave portion.

With this structure, by bringing the tip end of the convex portion into contact with the bottom portion of the concave portion, the supporting portion can support the holding portion in a state where it is tiltable with respect to the substrate.

The concave portion may be formed on the base portion, and the supporting portion may be a convex portion that is fixed to the second surface, protrudes toward the base portion, and comes into contact with a bottom portion of the concave portion.

With this structure, by bringing the tip end of the convex portion into contact with the bottom portion of the concave portion, the supporting portion can support the holding portion in a state where it is tiltable with respect to the substrate.

The concave portion may be formed on the second surface, and the supporting portion may be a convex portion that is fixed to the base portion, protrudes toward the holding portion, and comes into contact with a circumference of the concave portion.

With this structure, by the convex portion coming into line contact with the circumference of the concave portion and sliding, the supporting portion can support the holding portion in a state where it is tiltable with respect to the substrate.

The concave portion may be formed on the base portion, and the supporting portion may be a convex portion that is fixed to the second surface, protrudes toward the base portion, and comes into contact with a circumference of the concave portion.

With this structure, by the convex portion coming into line contact with the circumference of the concave portion and sliding, the supporting portion can support the holding portion in a state where it is tiltable with respect to the substrate.

The concave portion may be formed in a cylindrical shape on the base portion, and the supporting portion may be a conic convex portion that is fixed to the second surface, protrudes toward the base portion, and includes a bottom surface having a shape corresponding to that of a bottom surface of the concave portion.

With this structure, by the bottom surface of the convex portion tilting with respect to the bottom surface of the concave portion, the supporting portion can support the holding portion in a state where it is tiltable with respect to the substrate. Moreover, since the shape of the bottom surface of the convex portion corresponds to that of the bottom surface of the concave portion, a positional deviation of the supporting portion with respect to the base portion can be prevented from occurring.

The holding apparatus may further include a restricting portion that is provided between the base portion and the holding portion and prevents a positional deviation of the holding portion from occurring with respect to the base portion.

With this structure, the position of the holding portion with respect to the base portion can be maintained.

The first surface may be formed of a friction material.

With this structure, the holding object can be held by a frictional force of the friction material.

The friction material may be constituted of an electric adhesive element whose adhesive force can be controlled electrically.

With this structure, by enhancing the adhesive force when holding the holding object and lowering the adhesive force when releasing the holding object, a predetermined chuck function and an adequate de-chuck function with respect to the holding object can be obtained.

The electric adhesive element may include an insulating adhesive medium, an electric adhesive material constituted of dielectric micro-particles or semiconductor micro-particles dispersed in the adhesive medium, and an electrode that applies a voltage to the electric adhesive material.

With this structure, by controlling the voltage to be applied to the electrode, it is possible to cause the dielectric micro-particles or semiconductor micro-particles to move in the adhesive medium to thus change the adhesiveness of the electric adhesive material.

According to an embodiment of the present invention, there is provided a conveying apparatus conveying a conveying object, including a hand, a holding portion, and a supporting portion.

The hand includes a mounting surface on which the conveying object is mounted.

The holding portion includes a first surface that holds the conveying object and a second surface opposing the mounting surface.

The supporting portion is provided between the mounting surface and the second surface and supports the holding portion in a state where the holding portion is tiltable with respect to the mounting surface.

The conveying apparatus holds and conveys the holding object using the first surface of the holding portion. Since the holding portion is supported by the supporting portion such that it is tiltable with respect to the mounting surface, the holding portion easily follows the deformation of the substrate. Therefore, according to the conveying apparatus, it is possible to stably hold and convey the substrate irrespective of the shape of the conveying object.

According to an embodiment of the present invention, there is provided a rotation-transmitting apparatus including a first spinning disk, a transmitting portion, a concave portion, a supporting portion, an engaging portion, and a second spinning disk.

The transmitting portion includes a first surface and a second surface opposing the first spinning disk.

The concave portion is formed on either one of the first spinning disk and the second surface.

The supporting portion is constituted of an inelastic body, is provided between the first spinning disk and the second surface, and supports the transmitting portion in a state where the transmitting portion is tiltable with respect to the first spinning disk by engaging with the concave portion.

The engaging portion is provided on a circumference of the supporting portion and engages the first spinning disk and the transmitting portion in a rotating direction.

The second spinning disk comes into contact with the first surface.

With this structure, when transmitting the rotation of the first spinning disk to the second spinning disk or the rotation of the second spinning disk to the first spinning disk, the rotations can be stably transmitted even when rotational axes of the spinning disks tilt.

The first surface may be formed of a friction material.

With this structure, the rotation can be transmitted to the second spinning disk by the frictional force of the friction material.

The friction material may be constituted of an electric adhesive element whose adhesive force can be controlled electrically.

With this structure, a rotation transmitting force between the transmitting portion and the second spinning disk can be changed to a desired level.

Hereinafter, embodiments of the present invention will be described with reference to the drawings.

### First Embodiment

A conveying apparatus 1 according to a first embodiment will be described.

FIG. 1 is a perspective view showing the conveying apparatus 1. The conveying apparatus 1 of this embodiment is structured as a substrate conveying apparatus that conveys a substrate in vacuum or in the atmosphere.

As shown in the figure, the conveying apparatus 1 includes a driving portion 2, an arm 3, and a hand 4. The driving portion 2 is coupled to one end of the arm 3, and the hand 4 is coupled to the other end of the arm 3. Further, on the hand 4, a substrate W as a conveying object is mounted.

The driving portion 2 drives the arm 3. The driving portion 2 has a power source such as an electric motor and a power-transmitting mechanism incorporated therein so as to be capable of driving the arm 3. The structure of the driving portion 2 is not limited to that described above.

The arm 3 supports the hand 4. The arm 3 is structured to be capable of turning, expanding etc. by power transmitted from the driving portion 2 and moving the hand 4. The arm 3 has a multi-joint structure, but the structure is not limited thereto.

The hand 4 includes a supporting surface 4a (mounting surface) on which a holding mechanism 5 that holds the substrate W is provided. A holding force of the hand 4 with respect to the substrate W is variable. The hand 4 holds the substrate W with a predetermined holding force when receiving the substrate W from a substrate processing unit (not shown) and conveying it and releases the holding force when handing the substrate over to the substrate processing unit (not shown).

The structure of the hand 4 will be described in detail.

FIG. 2 is a perspective view showing the hand 4.

As shown in the figure, the hand 4 is formed of a metal material such as stainless steel or a ceramic material such as alumina and formed as a U-shaped plate. However, the shape of the hand 4 is not limited thereto. The hand 4 is attached to the arm 3 such that its surface becomes horizontal.

On the supporting surface 4a of the hand 4, three holding mechanisms 5 are provided. The number and arrangement of the holding mechanisms 5 can be changed as appropriate based on a size, shape, and the like of the conveying object.

The structure of the holding mechanisms 5 will be described in detail.

FIG. 3 is a cross-sectional diagram showing the holding mechanism 5.

As shown in the figure, the holding mechanisms 5 each include a pad 6 (holding portion) and a supporting member 7 (supporting portion). The pad 6 is supported by the supporting member 7 on the hand 4 (base portion).

The pad 6 is formed by laminating a substrate layer 8, an electrode layer 9, and an adhesive layer 10 (friction material). The pad 6 is formed in a disk shape, though not limited thereto. The substrate layer 8 is formed of an insulation material such as ceramic but may instead be formed of other inorganic or organic insulation materials. The substrate layer 8 includes a concave portion 8a that is formed at the center of the surface opposing the hand 4. The concave portion 8a has a shape that narrows from the opening portion to the back portion.

The electrode layer 9 is laminated on the surface of the substrate layer 8 on the other side of the surface that opposes the hand 4. The electrode layer 9 is formed to be capable of applying an electric field to the adhesive layer 10 and includes, for example, a pectinated electrode. The electrode layer 9 is connected to a wiring (not shown) connected to an external power source. The adhesive layer 10 is laminated on the electrode layer 9.

FIGS. 4(A) and 4(B) are schematic diagrams showing the adhesive layer 10.

As shown in the figures, the adhesive layer 10 is constituted of an adhesive medium 11 and electric rheology particles 12 dispersed in the adhesive medium 11.

The adhesive medium 11 is a gel-type insulation material such as a fluorine-based resin and a silicone resin and has an adhesive force.

The “electric rheology particles 12” is a collective term for a particle-type dielectric material, a particle-type semiconductor material, or a particle material as a complex of those two.

The adhesive medium 11 and the electric rheology particles 12 are combined so as to exert an electric adhesion effect.

The electric adhesion effect of the adhesive layer 10 will be described in detail.

FIG. 4(A) shows the adhesive layer 10 in a state where no voltage is applied, and FIG. 4(B) shows the adhesive layer 10 in a state where a voltage is applied.

In the state where no voltage is applied as shown in FIG. 4(A), the electric rheology particles 12 are dispersed in the adhesive layer 10 for separating from one another by viscoelasticity and are protruding from the front surface of the adhesive layer 10. Accordingly, the substrate W is prevented from directly coming into contact with the adhesive medium 11, and an adhesive force between the substrate W and the adhesive layer 10 becomes small (or is lost). When a voltage is applied to the electrode layer 9, the state shifts to the state where a voltage is applied as shown in FIG. 4(B).

In the state where a voltage is applied as shown in FIG. 4(B), the electric rheology particles 12 cause dielectric polarization by the voltage applied to the electrode layer 9 and aggregate on a line of electric force, which are exaggerated in the figure to help understand the description. The electric rheology particles 12 protruding from the front surface of the adhesive layer 10 sink in the adhesive medium 11. As a result, the substrate W and the adhesive medium 11 are brought into direct contact with each other, and the adhesive force between the substrate W and the adhesive layer 10 becomes large. The level of aggregation of the electric rheology particles depends on the level of voltage applied to the electrode layer 9. Therefore, it is possible to control the adhesive force based on the voltage level.

As described above, the adhesive force between the substrate W and the adhesive layer 10 can be adjusted based on whether a voltage is applied to the electrode layer 9.

The supporting member 7 is an inelastic body and formed of a metal material such as stainless steel. The supporting member 7 is formed in a columnar shape that has two ends. One end is fixed to the hand 4, and the other end (apex) is in point contact with the bottom portion of the concave portion 8a of the substrate layer 8. The supporting member 7 supports the pad 6 by the point contact. The end portion of the supporting member 7 on a side that is in contact with the concave portion 8a is formed in, for example, a conic shape that is sharper than the narrowing angle of the concave portion 8a, and the tip end of the end portion is in point contact with the concave portion 8a, with the result that a gap is caused between other portions and the concave portion 8a. Therefore, the substrate layer 8 (pad 6) is capable of tilting in all directions about the contact point. It should be noted that the point contact used herein means that the contact area is too small to prevent the pad 6 from tilting (practically a point) and does not strictly mean a point.

A tiltable angle of the pad 6 with respect to the surface of the hand 4 is a smaller one of the angle at which the concave portion 8a and the supporting member 7 come into contact with each other and the angle at which the pad 6 and the hand 4 come into contact with each other.

Since the concave portion 8a narrows toward the back portion from the opening thereof, the contact point of the supporting member 7 is constantly at the backmost portion of the concave portion, and a horizontal position of the pad 6 with respect to the hand 4 can be constantly maintained. Moreover, since the contact point (fulcrum) of the supporting member 7 is positioned above a barycenter of the pad 6 in the vertical direction, the pad 6 is maintained horizontally with respect to the surface of the hand 4 by a moment of a force even when the substrate W is not held.

Although the pad 6 is engaged with the supporting member 7 by being in contact therewith, since the substrate W is held by the adhesive layer 10 whose adhesive force can be arbitrarily caused to disappear, the pad 6 does not stick to the substrate W to be pulled out. A pull-out preventing mechanism for the pad 6 may be provided as necessary.

An operation of the thus-structured conveying apparatus 1 will be described.

The driving portion 2 drives the arm 3, and the hand 4 obtains the substrate W. This is realized by the hand 4 scooping up the substrate W supported by a lifter pin, for example. When the hand obtains the substrate W or before the hand obtains the substrate W, a voltage is applied to the electrode layer 9 of the holding mechanisms 5. As a result, the adhesive force of the adhesive layer 10 is kept high.

The substrate W is held by the holding mechanisms 5 of the hand 4.

FIG. 5 are schematic diagrams showing states where the holding mechanisms 5 are holding the substrate W.

As shown in FIG. 5(A), when the substrate W is brought into contact with the pad 6, the adhesive layer 10 of the pad 6 comes into contact with the substrate W to hold the substrate W. It should be noted that even when the pad 6 of the holding mechanisms 5 is tilted with respect to the hand 4 in a state where the substrate W is not held, by the surface of the substrate W coming into contact with the pad 6, the pad 6 is corrected to be set in the horizontal direction.

As shown in FIG. 5(B), even when the substrate W is warped with respect to the surface of the hand 4, since the pad 6 tilts with respect to the hand 4 in accordance with the surface of the substrate W, the entire surface of the adhesive layer 10 of the pad 6 comes into contact with the substrate W to thus hold the substrate W.

As the driving portion 2 is driven while the substrate W is held, the substrate W is moved. At a predetermined position, an application of a voltage to the electrode layer 9 is canceled. Accordingly, the adhesive force of the adhesive layer 10 becomes low, and the holding force of the substrate W is released, with the result that the substrate W can be demounted. It should be noted that during conveyance, some kind of processing (cooling etc.) may be carried out on the substrate W.

The substrate W is conveyed as described above. Even when a deformation such as a warpage is caused in the substrate W, by the pad 6 tilting in accordance with the surface of the substrate W, the entire surface of the adhesive layer 10 comes into contact with the substrate W so that the substrate W can be held stably. Further, since the supporting member 7 is constituted of an inelastic body, the supporting member 7 does not vibrate by an inertial force caused by the movement of the hand 4, with the result that the substrate W can be held stably.

### Second Embodiment

A conveying apparatus according to a second embodiment will be described.

In descriptions below, descriptions on parts having the same structures as those of the above embodiment will be simplified.

FIG. 6 is a cross-sectional diagram showing a holding mechanism 21 of the conveying apparatus.

As shown in the figure, the holding mechanism 21 includes a pad 22 (holding portion) and a supporting member 23 (supporting portion). The pad 22 is supported by the supporting member 23 on a hand 24 (base portion).

The pad 22 is formed by laminating a substrate layer 25, an electrode layer 26, and an adhesive layer 27 (friction material). The substrate layer 25, the electrode layer 26, and the adhesive layer 27 have the same structures as the substrate layer 8, the electrode layer 9, and the adhesive layer 10 of the first embodiment.

It should be noted that the substrate layer 25 of this embodiment includes a concave portion 25a that is formed at the center of the surface opposing the hand 24. The concave portion 25a is formed in a hemispherical shape or a semielliptical shape.

The supporting member 23 is an inelastic body and formed of metal or the like. The supporting member 23 is formed in a hemispherical shape or a semielliptical shape. The flat surface of the supporting member 23 is fixed to the hand 24, and the curved surface thereof is in contact with the concave portion 25a. Here, the supporting member 23 is formed in a hemispherical shape or a semielliptical shape having a smaller radius than the concave portion 25a or formed to have a larger curvature than the concave portion 25a. Accordingly, an apex of the curved surface of the supporting member 23 comes into point contact with the bottom portion of the concave portion 25a, with the result that a gap is caused between other portions and the concave portion 25a. Therefore, the pad 22 is capable of tilting in all directions about the contact point.

A tiltable angle of the pad 22 with respect to the hand 24 is a smaller one of the angle at which the concave portion 25a and the supporting member 23 come into contact with each other and the angle at which the pad 22 and the hand 24 come into contact with each other.

The substrate W is held and conveyed as described above. Even when a deformation such as a warpage is caused in the substrate W, by the pad 22 tilting in accordance with the surface of the substrate W, the entire surface of the adhesive layer 27 comes into contact with the substrate W so that the substrate W can be held stably. Further, since the supporting member 23 is constituted of an inelastic body, the supporting member 23 does not vibrate by an inertial force caused by the movement of the hand 24, with the result that the substrate W can be held stably.

### Third Embodiment

A conveying apparatus according to a third embodiment will be described.

In descriptions below, descriptions on parts having the same structures as those of the above embodiments will be simplified.

FIG. 7 is a cross-sectional diagram showing a holding mechanism 31 of the conveying apparatus.

As shown in FIG. 7, the holding mechanism 31 includes a pad 32 (holding portion) and a supporting member 33 (supporting portion). The pad 32 is supported by the supporting member 33 on a hand 34 (base portion). The hand 34 includes a concave portion 34a that is formed on the surface opposing the pad 32.

The pad 32 is formed by laminating a substrate layer 35, an electrode layer 36, and an adhesive layer 37 (friction material). The substrate layer 35, the electrode layer 36, and the adhesive layer 37 have the same structures as the substrate layer 8, the electrode layer 9, and the adhesive layer 10 of the first embodiment.

It should be noted that the substrate layer 35 of this embodiment does not have a concave portion on the surface opposing the hand 34.

The supporting member 33 is an inelastic body and formed of metal or the like. The supporting member 33 is formed in a columnar shape that has two ends. One end is fixed to the substrate layer 35, and the other end (apex) is in point contact with the bottom portion of the concave portion 34a. The supporting member 33 is formed to be thinner than an opening diameter of the concave portion 34a, and a viscoelastic body 38 is filled in the gap between the supporting member 33 and the concave portion 34a. The supporting member 33 fixed to the pad 32 is tiltable in all directions about the point contact with the hand 34 by viscoelasticity of the viscoelastic body 38. By changing the filling amount and material of the viscoelastic body 38, the tilting degree can be adjusted.

A tiltable angle of the pad 32 with respect to the hand 34 is the smallest one of the angle at which the concave portion 34a and the supporting member 33 come into contact with each other, the angle at which the pad 32 and the hand 34 come into contact with each other, and the allowable angle of the viscoelastic body 38.

Since the supporting member 33 is sealed in the hand 34 by the viscoelastic body 38, the horizontal position of the pad 32 with respect to the hand 34 can be constantly maintained. Moreover, the pad 32 (supporting member 33) is prevented from being released from the hand 34.

The substrate W is held and conveyed as described above. Even when a deformation such as a warpage is caused in the substrate W, by the pad 32 tilting in accordance with the surface of the substrate W, the entire surface of the adhesive layer 37 comes into contact with the substrate W so that the substrate W can be held stably. Further, since the supporting member 33 is constituted of an inelastic body, the supporting member 33 does not vibrate by an inertial force caused by the movement of the hand 34, with the result that the substrate W can be held stably.

### Fourth Embodiment

A conveying apparatus according to a fourth embodiment will be described.

In descriptions below, descriptions on parts having the same structures as those of the above embodiments will be simplified.

FIG. 8 is a cross-sectional diagram showing a holding mechanism 41 of the conveying apparatus.

As shown in FIG. 8, the holding mechanism 41 includes a pad 42 (holding portion) and a supporting member 43 (supporting portion). The pad 42 is supported by the supporting member 43 on a hand 44 (base portion). The hand 44 includes a concave portion 44a that is formed on the surface opposing the pad 42. The concave portion 44a is formed in a hemispherical shape or a semielliptical shape.

The pad 42 is formed by laminating a substrate layer 45, an electrode layer 46, and an adhesive layer 47 (friction material). The substrate layer 45, the electrode layer 46, and the adhesive layer 47 have the same structures as the substrate layer 8, the electrode layer 9, and the adhesive layer 10 of the first embodiment.

It should be noted that the substrate layer 45 of this embodiment does not have a concave portion on the surface opposing the hand 44.

The supporting member 43 is an inelastic body and formed of metal or the like. The supporting member 43 is formed in a hemispherical shape or a semielliptical shape. The flat surface of the supporting member 43 is fixed to the substrate layer 45, and the curved surface thereof is in contact with the concave portion 44a. Here, the supporting member 43 is formed in a hemispherical shape or a semielliptical shape having a smaller radius than the concave portion 44a or formed to have a larger curvature than the concave portion 44a. Accordingly, an apex of the curved surface of the supporting member 43 comes into point contact with the bottom portion of the concave portion 44a, with the result that a gap is caused between other portions and the concave portion 44a.

Therefore, the pad 42 is capable of tilting in all directions about the contact point.

A tiltable angle of the pad 42 with respect to the hand 44 is a smaller one of the angle at which the concave portion 44a and the supporting member 43 come into contact with each other and the angle at which the pad 42 and the hand 44 come into contact with each other.

The substrate W is held and conveyed as described above. Even when a deformation such as a warpage is caused in the substrate W, by the pad 42 tilting in accordance with the surface of the substrate W, the entire surface of the adhesive layer 47 comes into contact with the substrate W so that the substrate W can be held stably. Further, since the supporting member 43 is constituted of an inelastic body, the supporting member 43 does not vibrate by an inertial force caused by the movement of the hand 44, with the result that the substrate W can be held stably.

### Fifth Embodiment

A conveying apparatus according to a fifth embodiment will be described.

In descriptions below, descriptions on parts having the same structures as those of the above embodiments will be simplified.

FIG. 9 is a cross-sectional diagram showing a holding mechanism 51 of the conveying apparatus.

As shown in the figure, the holding mechanism 51 includes a pad 52 (holding portion) and a supporting member 53 (supporting portion). The pad 52 is supported by the supporting member 53 on a hand 54 (base portion).

The pad 52 is formed by laminating a substrate layer 55, an electrode layer 56, and an adhesive layer 57 (friction material). The substrate layer 55, the electrode layer 56, and the adhesive layer 57 have the same structures as the substrate layer 8, the electrode layer 9, and the adhesive layer 10 of the first embodiment.

It should be noted that the substrate layer 55 of this embodiment includes a concave portion 55a that is formed at the center of the surface opposing the hand 54. The concave portion 55a is formed in a hemispherical shape or a semielliptical shape.

The supporting member 53 is an inelastic body and formed of metal or the like. The supporting member 53 is formed in a hemispherical shape or a semielliptical shape. The flat surface of the supporting member 53 is fixed to the hand 54, and the curved surface thereof is in contact with the concave portion 55a. Here, the supporting member 53 is formed in a hemispherical shape or a semielliptical shape having a larger radius than the concave portion 55a or formed to have a smaller curvature than the concave portion 55a. Accordingly, an apex of the curved surface of the supporting member 53 does not come into contact with the bottom portion of the concave portion 55a, with the result that the oblique portion of the curved surface annularly comes into line contact with an opening edge (circumference) of the concave portion 55a.

By the concave portion 55a sliding on the supporting member 53, the pad 52 can tilt with respect to the hand 54.

The tiltable angle of the pad 52 with respect to the hand 54 is, at most, an angle at which the pad 52 comes into contact with the hand 54.

The substrate W is held and conveyed as described above. Even when a deformation such as a warpage is caused in the substrate W, by the pad 52 tilting in accordance with the surface of the substrate W, the entire surface of the adhesive layer 57 comes into contact with the substrate W so that the substrate W can be held stably. Further, since the supporting member 53 is constituted of an inelastic body, the supporting member 53 does not vibrate by an inertial force caused by the movement of the hand 54, with the result that the substrate W can be held stably.

### Sixth Embodiment

A conveying apparatus according to a sixth embodiment will be described.

In descriptions below, descriptions on parts having the same structures as those of the above embodiments will be simplified.

FIG. 10 is a cross-sectional diagram showing a holding mechanism 61 of the conveying apparatus.

As shown in FIG. 10, the holding mechanism 61 includes a pad 62 (holding portion) and a supporting member 63 (supporting portion). The pad 62 is supported by the supporting member 63 on a hand 64 (base portion).

The hand 64 includes a concave portion 64a that is formed on the surface opposing the pad 62. The concave portion 64a is formed in a hemispherical shape or a semielliptical shape.

The pad 62 is formed by laminating a substrate layer 65, an electrode layer 66, and an adhesive layer 67 (friction material). The substrate layer 65, the electrode layer 66, and the adhesive layer 67 have the same structures as the substrate layer 8, the electrode layer 9, and the adhesive layer 10 of the first embodiment.

It should be noted that the substrate layer 65 of this embodiment does not have a concave portion on the surface opposing the hand 64.

The supporting member 63 is an inelastic body and formed of metal or the like. The supporting member 63 is formed in a hemispherical shape or a semielliptical shape. The flat surface of the supporting member 63 is fixed to the substrate layer 65, and the curved surface thereof is in contact with the concave portion 64a. Here, the supporting member 63 is formed in a hemispherical shape or a semielliptical shape having a larger radius than the concave portion 64a or formed to have a larger curvature than the concave portion 64a. Accordingly, an apex of the curved surface of the supporting member 63 does not come into contact with the bottom portion of the concave portion 64a, with the result that the oblique portion of the curved surface annularly comes into line contact with an opening edge (circumference) of the concave portion 64a.

By the supporting member 63 sliding on the opening edge of the concave portion 64a, the pad 62 can tilt with respect to the hand 64.

The tiltable angle of the pad 62 with respect to the hand 64 is, at most, an angle at which the pad 62 comes into contact with the hand 64.

The substrate W is held and conveyed as described above. Even when a deformation such as a warpage is caused in the substrate W, by the pad 62 tilting in accordance with the surface of the substrate W, the entire surface of the adhesive layer 67 comes into contact with the substrate W so that the substrate W can be held stably. Further, since the supporting member 63 is constituted of an inelastic body, the supporting member 63 does not vibrate by an inertial force caused by the movement of the hand 64, with the result that the substrate W can be held stably.

### Seventh Embodiment

A conveying apparatus according to a seventh embodiment will be described.

In descriptions below, descriptions on parts having the same structures as those of the above embodiments will be simplified.

FIG. 11 is a cross-sectional diagram showing a holding mechanism 71 of the conveying apparatus.

As shown in the figure, the holding mechanism 71 includes a pad 72 (holding portion), a supporting member 73 (supporting portion), and restricting members 78 (restricting portion). The pad 72 is supported by the supporting member 73 on a hand 74 (base portion).

The pad 72 is formed by laminating a substrate layer 75, an electrode layer 76, and an adhesive layer 77 (friction material). The substrate layer 75, the electrode layer 76, and the adhesive layer 77 have the same structures as the substrate layer 8, the electrode layer 9, and the adhesive layer 10 of the first embodiment.

It should be noted that the substrate layer 75 of this embodiment includes a concave portion 75a that is formed at the center of the surface opposing the hand 74 and two concave portions 75b that are formed on an outer circumferential side of the same surface. The concave portion 75a is formed in a hemispherical shape or a semielliptical shape, and the concave portions 75b are formed in a cylindrical shape. The number of concave portions 75b is not limited to two.

The supporting member 73 is an inelastic body and formed of metal or the like. The supporting member 73 is formed in a hemispherical shape or a semielliptical shape. The flat surface of the supporting member 73 is fixed to the hand 74, and the curved surface thereof is in contact with the concave portion 75a. Here, the supporting member 73 is formed in a hemispherical shape or a semielliptical shape having a smaller radius than the concave portion 75a or formed to have a larger curvature than the concave portion 75a. Accordingly, an apex of the curved surface of the supporting member 73 comes into point contact with the bottom portion of the concave portion 75a, with the result that a gap is caused between other portions and the concave portion 75a. Therefore, the pad 72 is capable of tilting in all directions about the contact point.

A tiltable angle of the pad 72 with respect to the hand 74 is a smaller one of the angle at which the concave portion 75a and the supporting member 73 come into contact with each other and the angle at which the pad 72 and the hand 74 come into contact with each other.

The restricting members 78 are formed in a columnar shape and each have one end fixed to the hand 74 and the other end inserted into the concave portion 75b. The restricting members 78 are formed to have a smaller diameter than the concave portions 75b, and tip end portions of the restricting members 78 face the bottom portions of the concave portions 75b with gaps interposed therebetween. Accordingly, the pad 72 is not inhibited from tilting by the restricting members 78 with respect to the hand 74. The restricting members 78 engage with the concave portions 75b to prevent the supporting member 73 from disengaging from the concave portion 75a as the pad 72 moves horizontally with respect to the supporting member 73. In other words, the position of the pad 72 with respect to the hand 74 can be maintained.

The substrate W is held and conveyed as described above. Even when a deformation such as a warpage is caused in the substrate W, by the pad 72 tilting in accordance with the surface of the substrate W, the entire surface of the adhesive layer 77 comes into contact with the substrate W so that the substrate W can be held stably. Further, since the supporting member 73 is constituted of an inelastic body, the supporting member 73 does not vibrate by an inertial force caused by the movement of the hand 74, with the result that the substrate W can be held stably.

The disengagement preventing mechanism for the pad 72 that uses the restricting members 78 and the concave portions 75b of this embodiment is also effective when applied to conveying apparatuses of other embodiments, in particular, the conveying apparatuses according to the fourth, fifth, and sixth embodiments in which the supporting members have curved surfaces.

### Eighth Embodiment

A conveying apparatus according to an eighth embodiment will be described.

In descriptions below, descriptions on parts having the same structures as those of the above embodiments will be simplified.

FIG. 12 is a cross-sectional diagram showing a holding mechanism 81 of the conveying apparatus.

As shown in FIG. 12, the holding mechanism 81 includes a pad 82 (holding portion) and a supporting member 83 (supporting portion). The pad 82 is supported by the supporting member 83 on a hand 84 (base portion). The hand 84 includes a cylindrical concave portion 84a on the surface opposing the pad 82.

The pad 82 is formed by laminating a substrate layer 85, an electrode layer 86, and an adhesive layer 87 (friction material). The substrate layer 85, the electrode layer 86, and the adhesive layer 87 have the same structures as the substrate layer 8, the electrode layer 9, and the adhesive layer 10 of the first embodiment.

In particular, the substrate layer 85 of this embodiment does not have a concave portion on the surface opposing the hand 84.

The supporting member 83 is an inelastic body and formed of metal or the like. The supporting member 83 is formed in a conic trapezoidal shape. The supporting member 83 includes two bottom surfaces. The bottom surface having a smaller area is referred to as bottom surface 83c, and the bottom surface having a larger area is referred to as bottom surface 83d. The bottom surface 83c is fixed to the substrate layer 85, and the bottom surface 83d is in contact with the concave portion 84a. Here, the supporting member 83 is formed such that the bottom surface 83d matches the shape of the bottom surface of the concave portion 84a. Accordingly, the bottom surface 83d is capable of moving from the bottom surface of the concave portion 84a using one point on the circumference of the bottom surface 83d as a fulcrum, that is, the pad 82 is capable of tilting with respect to the hand 84.

A tiltable angle of the pad 82 with respect to the hand 84 is, at most, an angle at which the pad 82 or the supporting member 83 comes into contact with the hand 84.

The substrate W is held and conveyed as described above. Even when a deformation such as a warpage is caused in the substrate W, by the pad 82 tilting in accordance with the surface of the substrate W, the entire surface of the adhesive layer 87 comes into contact with the substrate W so that the substrate W can be held stably. Further, since the supporting member 83 is constituted of an inelastic body, the supporting member 83 does not vibrate by an inertial force caused by the movement of the hand 84, with the result that the substrate W can be held stably.

### Ninth Embodiment

A conveying apparatus according to a ninth embodiment will be described.

In descriptions below, descriptions on parts having the same structures as those of the above embodiments will be simplified.

FIG. 13 is a cross-sectional diagram showing a holding mechanism 201 of the conveying apparatus.

As shown in FIG. 13, the holding mechanism 201 includes a pad 202 (holding portion) and a supporting member 203. The pad 202 is supported by the supporting member 203 on a hand 204 (base portion).

The pad 202 is formed by laminating a substrate layer 205, an electrode layer 206, and an adhesive layer 207 (friction material). The substrate layer 205, the electrode layer 206, and the adhesive layer 207 have the same structures as the substrate layer 8, the electrode layer 9, and the adhesive layer 10 of the first embodiment.

The supporting member 203 is a coil spring, and both ends thereof are fixed to the hand 204 and the substrate layer 205, respectively. By an elastic deformation of the supporting member 203, the pad 202 can tilt with respect to the hand 204. A tiltable angle of the pad 202 with respect to the hand 204 is, at most, an angle at which the pad 202 comes into contact with the hand 204.

The substrate W is held and conveyed as described above. Even when a deformation such as a warpage is caused in the substrate W, by the pad 202 tilting in accordance with the surface of the substrate W, the entire surface of the adhesive layer 207 comes into contact with the substrate

W so that the substrate W can be held stably.

### Tenth Embodiment

A conveying apparatus according to a tenth embodiment will be described.

In descriptions below, descriptions on parts having the same structures as those of the above embodiments will be simplified.

FIG. 14 is a cross-sectional diagram showing a holding mechanism 211 of the conveying apparatus.

As shown in FIG. 14, the holding mechanism 211 includes a pad 212 (holding portion) and a supporting member 213. The pad 212 is supported by the supporting member 213 on a hand 214 (base portion).

The pad 212 is formed by laminating a substrate layer 215, an electrode layer 216, and an adhesive layer 217 (friction material). The substrate layer 215, the electrode layer 216, and the adhesive layer 217 have the same structures as the substrate layer 8, the electrode layer 9, and the adhesive layer 10 of the first embodiment.

The supporting member 213 is constituted of a supporting shaft 213a and a plate spring 213b. The supporting shaft 213a is constituted of an inelastic body and has one end thereof fixed to the substrate layer 215 and the other end thereof fixed to the plate spring 213b. The plate spring 213b is fixed to the hand 214 and capable of being elastically deformed when applied with a force by the supporting shaft 213a. Specifically, as the plate spring 213b, a plate-type elastic member that is bridged above a concave portion 214a formed in the hand 214 can be used. In this case, the plate spring 213b can be elastically deformed using a gap formed between the concave portion 214a. Further, by being bridged radially about the point at which the supporting shaft 213a is fixed, the plate spring 213b can be elastically deformed in all directions. The structure of the plate spring 213b is not limited to such a structure, and a curved plate can also be used for securing the gap between the hand 214.

By the elastic deformation of the plate spring 213b, the pad 212 can tilt with respect to the hand 214. A tiltable angle of the pad 212 with respect to the hand 214 is, at most, an angle at which the pad 212 comes into contact with the hand 214.

The substrate W is held and conveyed as described above. Even when a deformation such as a warpage is caused in the substrate W, by the pad 212 tilting in accordance with the surface of the substrate W, the entire surface of the adhesive layer 217 comes into contact with the substrate W so that the substrate W can be held stably.

### Eleventh Embodiment

In a rotation-transmitting apparatus that transmits a rotation by a driving disk and a driven disk coming into contact with each other, a rotational axis of the driving disk and that of the driven disk need to be coaxial. For example, when the rotational axis of the driving disk and that of the driven disk tilt by a vibration and the like, there is a fear that a load on a contact surface between the driving disk and the driven disk may lose its uniformity and an inconvenience such as a lopsided abrasion may occur. Therefore, an alignment mechanism or the like for keeping the rotation axes on the same axis becomes necessary. Here, for the rotation-transmitting apparatus according to this embodiment, a rotation-transmitting apparatus that allows a tilt of the rotation axes will be described.

FIG. 15 are cross-sectional diagrams each showing a rotation-transmitting apparatus 90.

As shown in FIG. 15(A), the rotation-transmitting apparatus 90 includes a driving axis 91, a driving disk 92 (first spinning disk), a transmitting mechanism 93, a driven disk 94 (second spinning disk), and a driven axis 95. The driving disk 92 is connected to the driving axis 91, and the driven disk 94 is connected to the driven axis 95. The driving disk 92 and the driven disk 94 face each other via the transmitting mechanism 93. It should be noted that it is also possible to use the driving axis 91 as a driven axis and the driven axis 95 as a driving axis.

The driving axis 91 is connected to an external driving source and rotates about an axis thereof.

The driving disk 92 rotates together with the driving axis 91. The driving disk 92 is formed in a disk shape.

The transmitting mechanism 93 transmits a rotation of the driving disk 92 to the driven disk 94 or does not transmit it at all, the details of which will be described later.

The driven disk 94 rotates based on the rotation transmitted from the transmitting mechanism 93. The driven disk 94 is formed in a disk shape.

The driven axis 95 rotates together with the rotation of the driven disk 94 and transmits the rotation to an external mechanism.

The structure of the transmitting mechanism 93 will be described in detail.

As shown in FIG. 15(A), the transmitting mechanism 93 includes a plate 96 (transmitting portion), a supporting member 97 (supporting portion), and rotation-transmitting pins 98 (engaging portion). The plate 96 is supported by the supporting member 97 on the driving disk 92 (first spinning disk).

The plate 96 has a disk shape and formed by laminating a substrate layer 99, an electrode layer 100, and an adhesive layer 101 (friction material). The substrate layer 99 is formed of an insulation material and includes a concave portion 99a that is formed at the center of the surface opposing the driving disk 92 and two concave portions 99b that are formed on an outer circumferential portion of the same surface. The concave portion 99a is formed in a hemispherical shape or a semielliptical shape. The concave portions 99b are formed in a cylindrical shape.

The electrode layer 100 is laminated on the surface of the substrate layer 99 on the other side of the surface opposing the driving disk 92. The electrode layer 100 is formed to be capable of applying an electric field to the adhesive layer 101 formed of an electric adhesive material as in the first embodiment and includes, for example, a pectinated electrode. The electrode layer 100 is connected to a wiring (not shown) connected to an external power source. The adhesive layer 101 is laminated on the electrode layer 100 and is in contact with the driven disk 94 (adhered to driven disk 94).

The supporting member 97 is formed in a hemispherical shape or a semielliptical shape. The flat surface of the supporting member 97 is fixed to the driving disk 92, and the curved surface thereof is in contact with the concave portion 99a. Here, the supporting member 97 is formed in a hemispherical shape or a semielliptical shape having a smaller radius than the concave portion 99a or formed to have a larger curvature than the concave portion 99a. Accordingly, an apex of the curved surface of the supporting member 97 comes into point contact with the bottom portion of the concave portion 99a, with the result that a gap is caused between other portions and the concave portion 99a. Therefore, the plate 96 is capable of tilting in all directions about the contact point.

The rotation-transmitting pins 98 transmit the rotation of the driving disk 92 to the plate 96. The rotation-transmitting pins are cylindrical and each have one end fixed to the driving disk 92 and the other end inserted into the concave portion 99b. The rotation-transmitting pins have a smaller diameter than the concave portions 99b and does not inhibit the plate 96 from tilting with respect to the driving disk 92.

An operation of the thus-structured rotation-transmitting apparatus 90 will be described.

The driving axis 91 and the driving disk 92 are rotated by an external driving source.

The rotation of the driving disk 92 is transmitted to the plate 96 by the rotation-transmitting pins 98.

When a voltage is not applied to the electrode layer 100 of the plate 96, the driven disk 94 does not rotate since the adhesive force (frictional force) between the adhesive layer 101 and the driven disk 94 is small.

When a predetermined voltage is applied to the electrode layer 100 of the plate 96, the driven disk 94 is rotated by an increased adhesive force (frictional force) between the adhesive layer 101 and the driven disk 94. The rotation is transmitted to the driven axis 95 connected to the driven disk 94.

As a result, it is possible to switch whether to transmit the rotation of the driving axis 91 to the driven axis 95 based only on a voltage application to the electrode layer 100.

Moreover, a transmitting torque of the driving disk 92 can be set variably by differentiating the fluidity of the adhesive layer 101 based on the level of voltage applied to the electrode layer 100. As a result, a torque limit can be set with ease.

FIG. 15(B) is a diagram showing a tilted state of the plate 96.

As shown in the figure, when the driven disk 94 tilts with respect to the driving disk 92, since the plate 96 of this embodiment is structured to be capable of tilting with respect to the driving disk 92, it is possible for the entire surface of the adhesive layer 101 to adhere onto the driven disk 94 so as to transmit the rotation. Therefore, even when the rotation axes of the driving axis 91 and driven axis 95 tilt and the driving disk 92 and the driven disk 94 are not in parallel, a rotation driving force can be appropriately transmitted to the driven axis 95.

By providing the adhesive layer 101 formed of an electric adhesive material in the rotation-transmitting apparatus 90 of this embodiment and controlling a voltage with respect to the electrode layer 100, the rotation-transmitting force becomes variable. On the other hand, when constantly transmitting a rotational force of the driving disk to the driven disk, it is possible to use a viscoelastic material for the adhesive layer 101 instead of the electric adhesive material. Moreover, instead of the adhesive layer 101, it is also possible to form a layer in a shape that intermeshes with the driven disk 94 (e.g., concavo-convex shape or shape of cutting blade) using a non-adhesive material such as metal so as to mechanically engage those two by bringing them into contact with each other. In this case, as in the above example, even when the rotation axes of the driving axis 91 and the driven axis 95 tilt, the rotation can be transmitted stably.

The present invention is not limited to the embodiments above and can be variously modified without departing from the gist of the present invention.

The embodiments above have shown the structure for holding an object using a friction material, but the object may be held using other structures. For example, an electrostatic chuck may be used as the holding portion or the transmitting portion. Further, the friction material is also not limited to that constituted of an electric adhesive element. Elastomer or the like may also be used.

The embodiments above have shown the example of the conveying apparatus and rotation-transmitting apparatus to which the present invention is applied. However, the application is not limited thereto.

### DESCRIPTION OF SYMBOLS

1 conveying apparatus
4 hand (base portion)
5 holding mechanism
6 pad (holding portion)
7 supporting member
8 substrate layer
8a concave portion
9 electrode layer
10 adhesive layer
11 adhesive medium
12 electric rheology particle
21 holding mechanism
22 pad (holding portion)
23 supporting member
24 hand (base portion)
25 substrate layer
25a concave portion
26 electrode layer
27 adhesive layer
31 holding mechanism
32 pad (holding portion)
33 supporting member
34 hand (base portion)
34a concave portion
35 substrate layer
36 electrode layer
37 adhesive layer
41 holding mechanism
42 pad (holding portion)
43 supporting member
44 hand (base portion)
44a concave portion
45 substrate layer
46 electrode layer
47 adhesive layer
47a concave portion
51 holding mechanism
52 pad (holding portion)
53 supporting member
54 hand (base portion)
55 substrate layer
55a concave portion
56 electrode layer
57 adhesive layer
61 holding mechanism
62 pad (holding portion)
63 supporting member
64 hand (base portion)
64a concave portion
65 substrate layer
66 electrode layer
67 adhesive layer
71 holding mechanism
72 pad (holding portion)
73 supporting member
74 hand (base portion)
75 substrate layer
75a concave portion
75b concave portion
76 electrode layer
77 adhesive layer
78 restricting member
81 holding mechanism
82 pad (holding portion)
83 supporting member
83c bottom surface
83d bottom surface
84 hand (base portion)
84a concave portion
85 substrate layer
86 electrode layer
87 adhesive layer
90 rotation-transmitting apparatus
91 driving axis
92 driving disk (first spinning disk)
93 transmitting mechanism
94 driven disk (second spinning disk)
95 driven axis
96 plate (transmitting portion)
97 supporting member (supporting portion)
98 rotation-transmitting pin
99 substrate layer
99a concave portion
99b concave portion
100 electrode layer
101 adhesive layer
201 holding mechanism
202 pad (holding portion)
203 supporting member
204 hand
205 substrate layer
206 electrode layer
207 adhesive layer
211 holding mechanism
212 pad (holding portion)
213 supporting member
214 hand
215 substrate layer
216 electrode layer
217 adhesive layer 217

1. A holding apparatus, comprising:
a base portion;
a holding portion including a first surface that holds a holding object and a second surface opposing the base portion; and
a supporting portion that is provided between the base portion and the second surface and supports the holding portion in a state where the holding portion is tillable with respect to the base portion.

2. The holding apparatus according to claim 1,
wherein either one of the base portion and the second surface includes a concave portion formed thereon, and
wherein the supporting portion is constituted of an inelastic body and engages with the concave portion.

3. The holding apparatus according to claim 1,
wherein the supporting body is constituted of an elastic body.

4. The holding apparatus according to claim 2,
wherein the concave portion is formed on the second surface, and
wherein the supporting portion is a convex portion that is fixed to the base portion, protrudes toward the holding portion, and comes into contact with a bottom portion of the concave portion.

5. The holding apparatus according to claim 2,
wherein the concave portion is formed on the base portion, and
wherein the supporting portion is a convex portion that is fixed to the second surface, protrudes toward the base portion, and comes into contact with a bottom portion of the concave portion.

6. The holding apparatus according to claim 2,
wherein the concave portion is formed on the second surface, and
wherein the supporting portion is a convex portion that is fixed to the base portion, protrudes toward the holding portion, and comes into contact with a circumference of the concave portion.

7. The holding apparatus according to claim 2,
wherein the concave portion is formed on the base portion, and
wherein the supporting portion is a convex portion that is fixed to the second surface, protrudes toward the base portion, and comes into contact with a circumference of the concave portion.

8. The holding apparatus according to claim 2,
wherein the concave portion is formed in a cylindrical shape on the base portion, and
wherein the supporting portion is a conic convex portion that is fixed to the second surface, protrudes toward the base portion, and includes a bottom surface having a shape corresponding to that of a bottom surface of the concave portion.

9. The holding apparatus according to claim 1, further comprising
a restricting portion that is provided between the base portion and the holding portion and prevents a positional deviation of the holding portion from occurring with respect to the base portion.

10. The holding apparatus according to claim 1,
wherein the first surface is formed of a friction material.

11. The holding apparatus according to claim 10,
wherein the friction material is constituted of an electric adhesive element whose adhesive force can be controlled electrically.

12. The holding apparatus according to claim 11,
wherein the electric adhesive element includes an insulating adhesive medium, an electric adhesive material constituted of dielectric micro-particles or semiconductor micro-particles dispersed in the adhesive medium, and an electrode that applies a voltage to the electric adhesive material.

13. A conveying apparatus conveying a conveying object, comprising:
a hand including a mounting surface on which the conveying object is mounted;
a holding portion including a first surface that holds the conveying object and a second surface opposing the mounting surface; and
a supporting portion that is provided between the mounting surface and the second surface and supports the holding portion in a state where the holding portion is tiltable with respect to the mounting surface.

14. A rotation-transmitting apparatus, comprising:
a first spinning disk;
a transmitting portion including a first surface and a second surface opposing the first spinning disk;
a concave portion formed on either one of the first spinning disk and the second surface;
a supporting portion that is constituted of an inelastic body, is provided between the first spinning disk and the second surface, and supports the transmitting portion in a state where the transmitting portion is tiltable with respect to the first spinning disk by engaging with the concave portion;
an engaging portion that is provided on a circumference of the supporting portion and engages the first spinning disk and the transmitting portion in a rotating direction; and
a second spinning disk that comes into contact with the first surface.

15. The rotation-transmitting apparatus according to claim 14,
wherein the first surface is formed of a friction material.

16. The rotation-transmitting apparatus according to claim 15,
wherein the friction material is constituted of an electric adhesive element whose adhesive force can be controlled electrically.
